(19) United States
(12) Patent Application Publication
(10) Pub. No.: US 2024/0379623 A1
(43) Pub. Date: Nov. 14, 2024

(54) SEMICONDUCTOR PACKAGE STRUCTURE AND METHOD FOR FORMING THE SAME

(71) Applicant: AP MEMORY TECHNOLOGY CORPORATION, HSINCHU COUNTY (TW)

(72) Inventors: WENLIANG CHEN, HSINCHU COUNTY (TW); CHIN-HUNG LIU, HSINCHU COUNTY (TW); KEE-WEI CHUNG, HSINCHU COUNTY (TW); RU-YI CAI, HSINCHU COUNTY (TW)

(21) Appl. No.: 18/657,010

(22) Filed: May 7, 2024

Related U.S. Application Data
(60) Provisional application No. 63/466,125, filed on May 12, 2023.

(51) Int. Cl. H01L 25/065; H01L 21/768; H01L 23/00; H01L 23/48; H01L 23/522; H10B 80/00

(52) U.S. Cl. CPC H01L 25/0657; H01L 21/76898; H01L 23/481; H01L 23/5226; H01L 24/32; H01L 24/83; H10B 80/00; H01L 2224/32145; H01L 2224/83896

(57) ABSTRACT

A semiconductor package structure is provided. The semiconductor package structure includes a first semiconductor structure, a dielectric bonding structure, a second semiconductor structure, and a through via structure. The first semiconductor structure includes a first substrate and a first back-end-of-line (BEOL) structure over the first substrate. The dielectric bonding structure is over the first semiconductor structure. The second semiconductor structure is over the dielectric bonding structure. The second semiconductor structure includes a second BEOL structure over the dielectric bonding structure and a second substrate over the second BEOL structure. The through via structure penetrates the second semiconductor structure and the dielectric bonding structure to connect the first BEOL structure and the second BEOL structure. A method for forming a semiconductor package structure is also provided.

### PRIORITY CLAIM AND CROSS-REFERENCE

This application claims the benefit of prior-filed U.S. provisional application No. 63/466,125, filed on May 12, 2023, and incorporates its entirety herein.

### FIELD

The present disclosure relates to a semiconductor package structure, particularly, the semiconductor package structure includes one or more through oxide vias (TOVs) for electrically connecting the stacked semiconductor wafers. By using the TOVs, the cost in stacking semiconductor wafers for the applications such as high performance computing (HPC) and/or artificial intelligence (AI) can be reduced significantly.

### BACKGROUND

Semiconductor packaging refers to the process of enclosing a semiconductor device in a protective casing to protect it from external damage and to facilitate its integration into electronic systems.

In some examples, the technique of heterogeneous integration helps semiconductor companies combine chiplets based on a variety of functions enabling the combination to perform as a single product. The need for transistors in applications like high-performance computing and artificial intelligence continues to increase at an exponential rate, while the ability to shrink transistors with classic 2D scaling is slowing and becoming more expensive. In some comparative embodiments, chip makers might integrate chiplets into advanced 2.5D and 3D packages structures using through-silicon vias (TSVs) and/or hybrid bonding. Through-silicon vias allow designers to increase performance and reduce power consumption, compared to the legacy chip on PCB approach.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 illustrates a cross-sectional view of a semiconductor package structure according to some embodiments of the present disclosure.

FIG. 2 illustrates a cross-sectional view of a semiconductor package structure according to some embodiments of the present disclosure.

FIG. 3A illustrates a cross-sectional view of a semiconductor package structure according to some embodiments of the present disclosure.

FIG. 3B illustrates a cross-sectional view of a semiconductor package structure according to some embodiments of the present disclosure.

FIG. 4 illustrates a cross-sectional view of a portion of a semiconductor package structure according to some embodiments of the present disclosure.

FIG. 5A illustrates a three-dimensional diagram of a connection between a through via structure and a metal line in a semiconductor package structure according to some embodiments of the present disclosure.

FIG. 5B illustrates a three-dimensional diagram of a connection between a through via structure and a metal line in a semiconductor package structure according to some embodiments of the present disclosure.

FIG. 6 illustrates a cross-sectional view of a semiconductor package structure according to some embodiments of the present disclosure.

FIGS. 7A-7G illustrate cross-sectional views of a process in preparing a semiconductor structure for semiconductor packaging according to some embodiments of the present disclosure.

FIGS. 8A and 8B illustrate cross-sectional views of a process in preparing a semiconductor structure for semiconductor packaging according to some embodiments of the present disclosure.

FIGS. 9A-9F illustrate cross-sectional views of a method for forming a semiconductor package structure according to some embodiments of the present disclosure.

FIGS. 10A and 10B illustrate cross-sectional views of a method for forming a semiconductor package structure according to some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer, or section from another. The terms such as “first”, “second”, and “third” when used herein do not imply a sequence or order unless clearly indicated by the context.

In 3DIC stacking technology today, the mainstream in the market includes chip-on-wafer (CoW) and wafer-on-wafer (WoW) technology. CoW technology can be applied to connect semiconductor dies by micro bumps and through silicon vias (TSV) connections, and WoW technology can be applied to connect two semiconductor wafers directly using hybrid bonding and TSV connections.

In some comparative embodiments, the hybrid bonding structure and TSV connections are used to provide electrical connection among the stacked semiconductor wafers, and thus obtain good density of packaging and high-speed data transmission, which can meet the requirements of high performance computing (HPC)/artificial intelligence (AI) applications, but it suffers from high manufacturing cost in the processes of the formation of the hybrid bonding structure, the formation of the TSVs, and the hybrid bonding for wafer stacking.

Therefore, in some embodiments of the present disclosure, a semiconductor package structure and a method for forming a semiconductor package structure are provided, wherein the processes of the formation of the hybrid bonding structure, the formation of the TSVs, and the hybrid bonding for wafer stacking can be avoided. In some embodiments of the present disclosure, one or more through oxide vias (TOVs) can be formed to electrically connect the stacked semiconductor wafers, and these semiconductor wafers can be bonded by fusion bonding through the dielectric material.

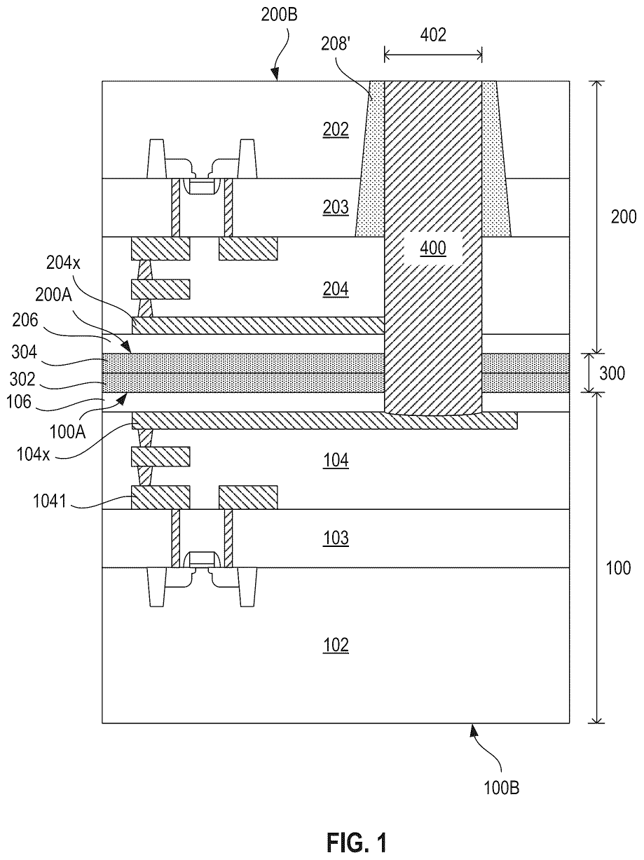

Referring to FIG. 1, in some embodiment, the semiconductor package structure includes a first semiconductor structure 100, a second semiconductor structure 200, and a dielectric bonding structure 300. The first semiconductor structure 100 has a first surface 100A and a second surface 100B opposite to the first surface 100A. The first semiconductor structure 100 includes a first substrate 102 in proximity to the second surface 100B of the first semiconductor structure 100, and a first back-end-of-line (BEOL) structure 104 over the first substrate 102. As the example shown in FIG. 1, the first BEOL structure 104 may be an interconnect section that includes a metallization structure that has a plurality of metal layers (e.g., M1, M2 . . . , Mx) electrically coupled by metal vias. In some embodiments, the first semiconductor structure 100 further includes a first MEOL structure 103 between the first substrate 102 and the first BEOL structure 104, and the first BEOL structure 104 includes a first metal layer (M1) 1041 that is directly in contact with a top surface of the first MEOL structure 103. In some embodiments, the first semiconductor structure 100 may include processors such as CPU or GPU manufactured from a logic wafer. In other embodiments, the first semiconductor structure 100 may include memories such as DRAM or HBM manufactured from a memory wafer. In other embodiments, the first semiconductor structure 100 may be a carrier wafer providing mechanical support during the manufacturing of the second semiconductor structure 200 since each of the second semiconductor structure 200 can be as thin as from 5 μm to 15 μm, and the carrier wafer can be removed after the stacking of the plurality of the second semiconductor structures 200. In other embodiments, the second semiconductor structure 200 may include memories such as DRAM or HBM manufactured from a memory wafer.

In some embodiments, the material of the first MEOL structure 103 includes dielectric material, which may be referred to as a pre-metal dielectric (PMD). In other words, the first MEOL structure 103 can be distinguished from the first substrate 102 there below and the first BEOL structure 104 thereon by a number of process parameters, such as the choice of the fundamental material, or the choice of the metal used. For instance, the material of the first MEOL structure 103 can include low-k dielectric material, silicon oxide-based dielectric material, silicon nitride-based dielectric material, or combinations thereof, and thus can be distinguished from the material of the first substrate 102; likewise, the metal usually used in the first MEOL structure 103 for electrical connect is tungsten (W), while the metal usually used in the first BEOL structure 104 is copper (Cu). These are several exemplary approaches to distinguish the stacked layers in the first semiconductor structure 100.

In some embodiments, the conductive material used in the first BEOL structure 104 may include copper (Cu), aluminum (Al), tungsten (W), titanium (Ti), titanium nitride (TIN), tantalum (Ta), tantalum nitride (TaN), or the like.

Above the first semiconductor structure 100, the dielectric bonding structure 300 is bonded over the first surface 100A of the first semiconductor structure 100. The second semiconductor structure 200 is bonded over the dielectric bonding structure 300. In some embodiments, the second semiconductor structure 200 includes a second BEOL structure 204 over the dielectric bonding structure 300 and a second substrate 202 over the second BEOL structure 204. That is, the positions of the first substrate 102 and the first BEOL structure 104 are mirrored to the second substrate 202 and the second BEOL structure 204 along the dielectric bonding structure 300.

In some embodiments, a through via structure 400 may located in the semiconductor package structure. The through via structure 400 penetrates the second semiconductor structure 200 and the dielectric bonding structure 300 to connect the first BEOL structure 104 and the second BEOL structure 204. That is, in some embodiments, the first semiconductor structure 100 and the second semiconductor structure 200 are bonded through the dielectric bonding structure 300 in face-to-face (F2F) scheme. In order to electrically connect the first semiconductor structure 100 and the second semiconductor structure 200, the through via structure 400 is utilized to couple the metal layers in the first BEOL structure 104 and the second BEOL structure 204. In some embodiments, the material of the through via structure 400 includes copper (Cu), aluminum (Al), tungsten (W), titanium (Ti), titanium nitride (TiN), tantalum (Ta), tantalum nitride (TaN), or the like.

As the example shown in FIG. 1, an end of the through via structure 400 in the semiconductor package structure can land on a metal layer in the first BEOL structure 104. In some embodiments, the metal layer in the first BEOL structure 104 for the landing of the through via structure 400 is the uppermost metal layer (Mx) 104x (i.e., the metal layer in proximity to the first surface 100A of the first semiconductor structure 100), while a lateral surface of the through via structure 400 is in contact with a metal layer (Mx) 204x of the second BEOL structure 204.

The second semiconductor structure 200 has a third surface 200A and a fourth surface 200B opposite to the third surface 200A. In some embodiments, another end of the through via structure 400 is located at the fourth surface 200B of the second semiconductor structure 200. The third surface 200A is in contact with the dielectric bonding structure 300. The second substrate 202 has a dielectric-filled structure 208′ formed therein, and a portion of the through via structure 400 in the second substrate 202 is surrounded by the dielectric-filled structure 208′. Generally, the entire portion of the through via structure 400 in the second substrate 202 can be substantially surrounded by the dielectric-filled structure 208′. However, depending on manufacturing tolerance, such as alignment between the through via structure 400 and the dielectric-filled structure 208′, in some embodiments, a portion of the through via structure 400 in the second substrate 202 may not be completely surrounded by the dielectric-filled structure 208′.

In some embodiments, the dielectric-filled structure 208′ is composed of a first dielectric material, and a dielectric constant (ε) of the dielectric-filled structure 208′ is smaller than 2.5, from 2.5 to 3.8, or from 3.8 to 4.8. The differences of the dielectric constant may be related to the type of the semiconductor structure to be bonded. For example, in the wafer for forming memory structures, the silicon oxide-based material usually have a regular dielectric constant in the range from about 3.8 to about 4.8, whereas in the wafer for forming the logic structure, the silicon oxide-based material usually have a low dielectric constant (i.e., low-k) in the range from about 2.5 to about 3.8. In the scenario where the through via structure 400 penetrates a high-end logic wafer which contains porous low-k material, the dielectric constant of the porous low-k material will be smaller than about 2.5.

In some embodiments, the material of the dielectric-filled structure 208′ includes silicon oxide-based material or metal oxide material. Accordingly, in some embodiments, other than the metal layers in contact with the through via structure 400 in the semiconductor package structure, the through via structure 400 is substantially surrounded by the silicon oxide-based material or the metal oxide material in the semiconductor package structure, including the dielectric-filled structure 208′, the pre-metal dielectric (PMD) in a second MEOL structure 203 in the second semiconductor structure 200, and the dielectric bonding structure 300. Therefore, in some embodiments, the through via structure 400 can be called a through oxide via (TOV).

In some embodiments, the PMD in the second MEOL structure 203 includes silicon oxide-based dielectric, silicon nitride-based dielectric, or combinations thereof. In some embodiments, a dielectric portion (e.g., called interlayer dielectric, ILD) in the second BEOL structure 204 includes a low-k dielectric material, such as BPSG or FSG, with a lower dielectric constant relative to that of silicon dioxide. In some embodiments, the dielectric constant of the PMD in the second MEOL structure 203 is different from the dielectric constant of the ILD in the second BEOL structure 204. Hence, the through via structure 400 can penetrate the stack of dielectric materials with different dielectric constants. Furthermore, the through via structure 400 can be substantially surrounded by a plurality of layers with different dielectric constants in the same layer, for example, the through via structure 400 in the second MEOL structure 203 is surrounded by the dielectric-filled structure 208′ with a first dielectric constant and the PMD in the second MEOL structure 203 with a second dielectric constant different from the first dielectric constant. Although not illustrated in FIG. 1, in some embodiments, the dielectric-filled structure 208′ may extend into a portion or an entirety of the second BEOL structure 204, in this connection, the through via structure 400 in the second BEOL structure 204 is surrounded by the dielectric-filled structure 208′ with a first dielectric constant and the ILD in the second BEOL structure 204 with a second dielectric constant different from the first dielectric constant.

From a process perspective, the forming of a TOV is much cost-effective than forming a TSV in the semiconductor package structure, because the formation of a trench in a dielectric material for filling the conductive material therein is easier than forming a trench in an alternative stack of silicon material (or other semiconductor material) and dielectric material. On the other hand, the semiconductor package structure in the present disclosure is cost-effective due to the simplified bonding structure. For instance, in some comparative embodiments, several pre-treatments to the bonding sides of the wafers are implemented in order to form the bonding layers before the bonding operation. In some examples, these bonding layers include hybrid bonding structures. After the formation of the hybrid bonding structures at each of the bonding sides of the wafers and the subsequent bonding operations, through silicon vias (TSVs) have to be formed to couple the conductive materials in the bonded wafers.

Accordingly, by using the TOV in the present disclosure, the stack of integrated circuits, no matter in a wafer-type or a die-type, can be waived from the high-cost forming of the bonding structures and electrical connection manner.

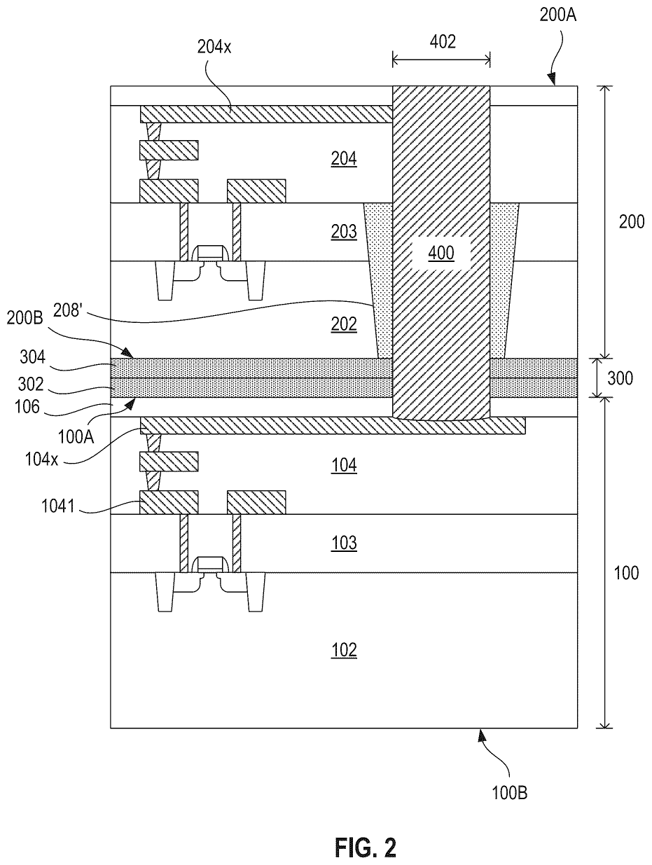

In some embodiments, the wafers or dies stacked as the semiconductor package structure in the present disclosure, e.g., the first semiconductor structure 100 and the second semiconductor structure 200 shown in FIG. 1, can be the wafers or dies including logic structures (e.g., processer including CPU, GPU, FPGA, ASIC, or the like) or memory structures (e.g., DRAM, SRAM, or the like). In some embodiments, the second semiconductor structure 200 can be stacked over the first semiconductor structure 100 in a face-down manner (i.e., a face-to-face (F2F) connection). In other embodiments, as shown in FIG. 2, the second semiconductor structure 200 can be stacked over the first semiconductor structure 100 in a face-up manner (i.e., a face-to-back (F2B) connection).

In some embodiments, the through via structure 400 is formed within a TOV region 402 of the second semiconductor structure 200. The TOV region 402 is a region in the second semiconductor structure 200 that is free from having a conductive material therein. That is, in the semiconductor package structure of the present disclosure, the through via structure 400 is formed in a single conductive material filling operation, where the trench of the dielectric material for filling the conductive material (i.e., the trench for forming the dielectric-filled structure) is not intervened by the conductive materials formed in previous operations. In other words, since the through via structure 400 penetrates the second semiconductor structure 200 and the dielectric bonding structure 300 to connect the first BEOL structure 104 and the second BEOL structure 204, the second BEOL structure 204 within the TOV region 402 does not include metal lines, metal vias, or the component that has conductive materials. In some embodiments, a width of the TOV region 402 is substantially narrower than a narrowest width of the dielectric-filled structure 208′, a widest width of the dielectric-filled structure 208′, or both. It is to ensure that the through via structure 400 can be formed within the projected area of the dielectric-filled structure 208′.

In some embodiments, a height of the dielectric-filled structure 208′ in the second substrate 202 is in a range from about 1 μm to about 10 μm. In some embodiments, there are multiple second semiconductor structures 200 stacked over the first semiconductor structure 100 and penetrated by the through via structure 400. In some embodiments, each of the second semiconductor structure may have a thickness in a range from about 5 μm to about 15 μm. In some embodiments, a height of the through via structure 400 penetrating these second semiconductor structures 200 is about 50 μm. In some embodiments, an aspect ratio of the through via structure 400 is less than about 10:1. In some comparative embodiments, an aspect ratio of a TSV in a semiconductor package structure is greater than about 10:1.

In some embodiments, the size of the dielectric-filled structure 208′ is changeable to accommodate multiple TOVs based on layout design and process capability in foundry. In some embodiments, a single semiconductor die may include thousands of TOVs for electrically connecting bonded structures therein.

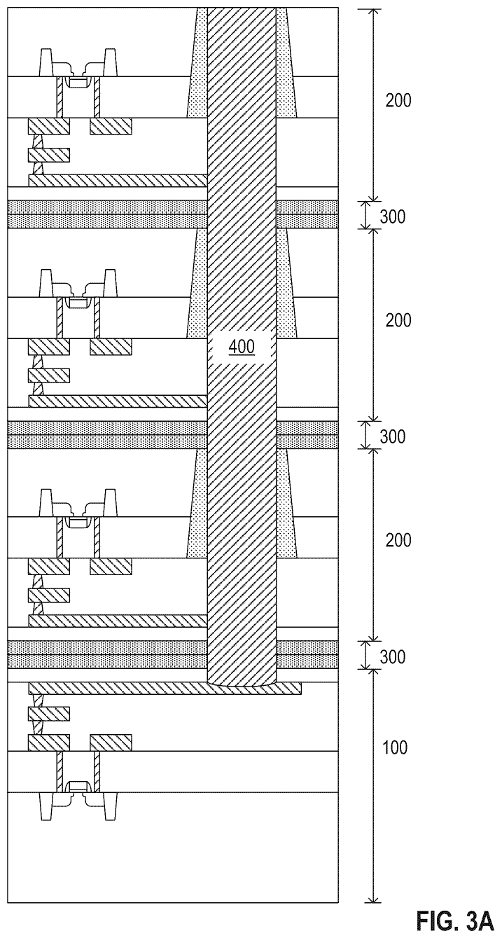

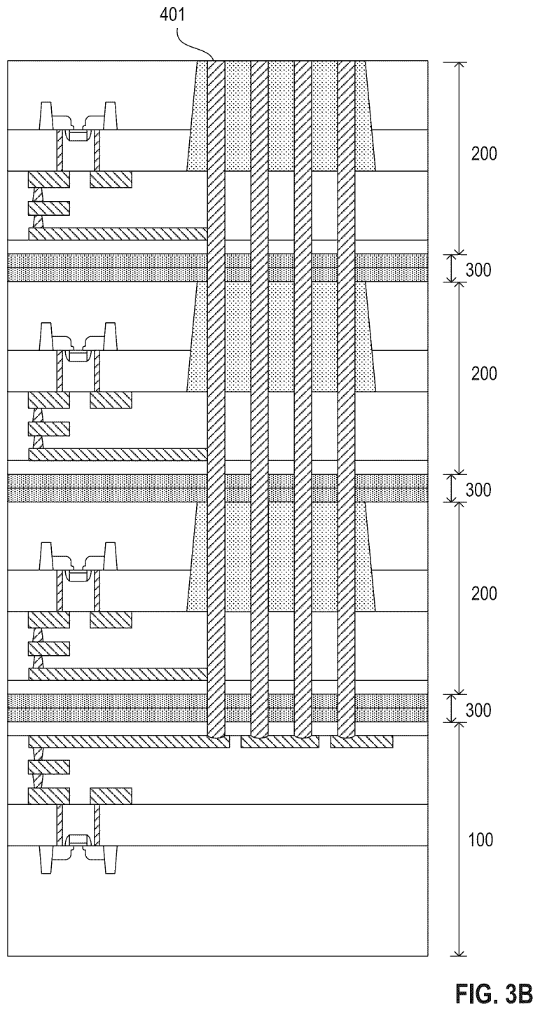

For example, referring to FIGS. 3A and 3B, which include three second semiconductor structures 200 stacked over the first semiconductor structure 100. As the embodiment shown in FIG. 3B, the through via structure 400 includes a plurality of through via units 401 landed on a same etch stop layer. In some embodiments, each of the through via units 401 penetrates the same dielectric-filled structure 208′ in each of the second semiconductor structures 200. That is, even though the through via structure 400 can be composed of the plurality of through via units 401 instead of a single conductive pillar in some embodiments, the number of the dielectric-filled structure 208′ in each of the second semiconductor structures 200 may maintain as one for all of the through via units 401 passing through. In some embodiments, an aspect ratio of each of the plurality of through via units 401 is less than about 10:1.

As shown in FIG. 3B, the through via units 401 can in contact with different metal lines in the same metal layer in the first BEOL structure 104, which reflect the design flexibility of the through via structure 400 in providing electrical connections within the semiconductor package structure.

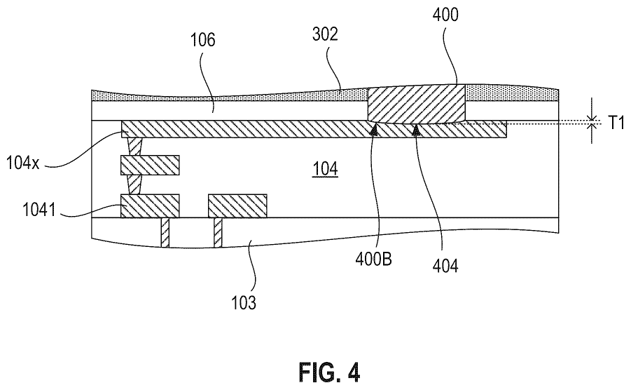

Referring to FIG. 4, in some embodiments, a bottom 400B of the through via structure 400 may have a protrusion 404 protrude towards the first BEOL structure 104. That is, a surface of the metal layer (e.g., the metal layer 104x) in the first BEOL structure 104 for the landing of the through via structure 400 may have a dishing profile corresponding to the protrusion 404 of the through via structure 400. The arc profile of the bottom 400B of the through via structure 400 may provide additional contacting surface between the metal layer in the first BEOL structure 104 and the bottom 400B of the through via structure 400. In some embodiments, a thickness T1 of the thickest portion of the protrusion 404 is no less than about 120 angstroms (Å) to ensure the reliability of the contact of the through via structure 400 and the metal layer in the first BEOL structure 104. The thickness T1 shall be thick enough to reduce electromigration impact to electrical connections such as metal layer 104x and the through via structure 400 because when the thickness T1 is no less than about 120 angstroms (Å), a sidewall of the through via structure 400 is in contact with a recessed portion of the metal layer 104x caused by dishing. However, the thickness T1 shall be not be too thick, e.g., greater than 500 Å, to induce stress migration or so-called stress-induced voiding in the electrical connections. Therefore, the thickness T1 of the thickest portion of the protrusion 404 is no less than about 120 angstroms (Å) and no greater than about 500 angstroms (Å).

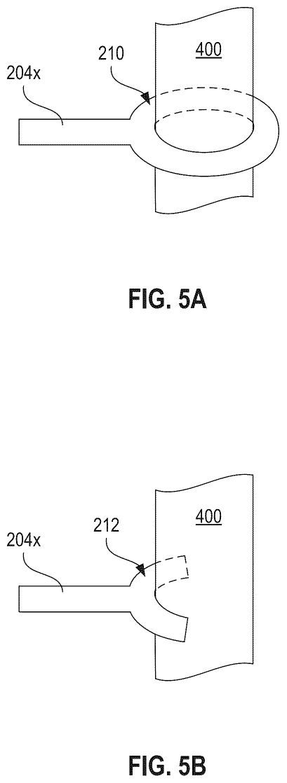

FIG. 4 is provided to illustrate the contact of the through via structure 400 and the metal layer 104x in the first BEOL structure 104, and FIGS. 5A and 5B are provided to illustrate the contact of the through via structure 400 and the metal layer 204x in the second BEOL structure 204. Referring to FIG. 5A, in some embodiments, the through via structure 400 is surrounded by a conductive pattern 210 in a type of ring (i.e., donut shaped) that is extended from the metal layer 204x of the second BEOL structure 204. In other embodiments, as shown in FIG. 5B, the through via structure 400 is at least partially surrounded by a conductive pattern 212 in a type of broken ring (i.e., pincer-shaped) that is extended from the metal layer 204x of the second BEOL structure 204. In some embodiments, at least ⅕ of the circumference of the through via structure 400 is in contact with the conductive pattern 212. In the circumstances where a plurality of second semiconductor structures 200 are stacked over the first semiconductor structure 100, the metal layers 204x in different second semiconductor structures 200 may be in contact with the same through via structure 400 through different conductive patterns. These embodiments may provide reduced contact resistance between the through via structure 400 and the metal layer in the second BEOL structure 204 comparing with the point contact there between, and therefore the manufacturing yield can be increased.

As previously shown in FIG. 1, in some embodiments, the dielectric bonding structure 300 (e.g., a first dielectric bonding structure 310) between the first semiconductor structure 100 and the second semiconductor structure 200 includes a first dielectric bonding layer 302 and a second dielectric bonding layer 304. In some embodiments, other than the through via structure 400, the first dielectric bonding layer 302 and a second dielectric bonding layer 304 are free from having conductive material at a bonding side thereof. That is, the first dielectric bonding layer 302 and second dielectric bonding layer 304 are utilized for fusion bonding under the condition where these dielectric bonding layers includes full-area dielectrics. Accordingly, the dielectric bonding structure 300 itself is lack of conductive material for the electrical connection between the first semiconductor structure 100 and the second semiconductor structure 200, and so that the through via structure 400 is subsequently formed after the fusion bonding of the first semiconductor structure 100 and the second semiconductor structure 200 by the first dielectric bonding layer 302 and a second dielectric bonding layer 304.

Likewise, within the stack of the multiple second semiconductor structures 200, the second dielectric bonding layers 304 of the second semiconductor structures 200 can be bonded to another dielectric bonding structure 300 (e.g., a second dielectric bonding structure 320) under the technique of fusion bonding. The through via structure 400 may laterally in contact with the metal layers in the second BEOL structures 204 in these second semiconductor structures 200, and so that each of the second semiconductor structures 200 in the stack of the multiple second semiconductor structures 200 can thus electrically connected with the first semiconductor structures 100.

In some embodiments, the through via structure 400 may continuously penetrate at least three of the second semiconductor structures 200 in the stack. In some embodiments, the through via structure 400 is free from directly in contact with a semiconductor device of a device section of the second semiconductor structure 200 (e.g., a section including FEOL structure and/or MEOL structure that some semiconductor devices such as transistor structures or capacitors can be formed or embedded therein). In other words, the through via structure 400 in some of the embodiments of the present disclosure is different from the typical TSVs that are used to electrical connect with the specific semiconductor device in the semiconductor wafers.

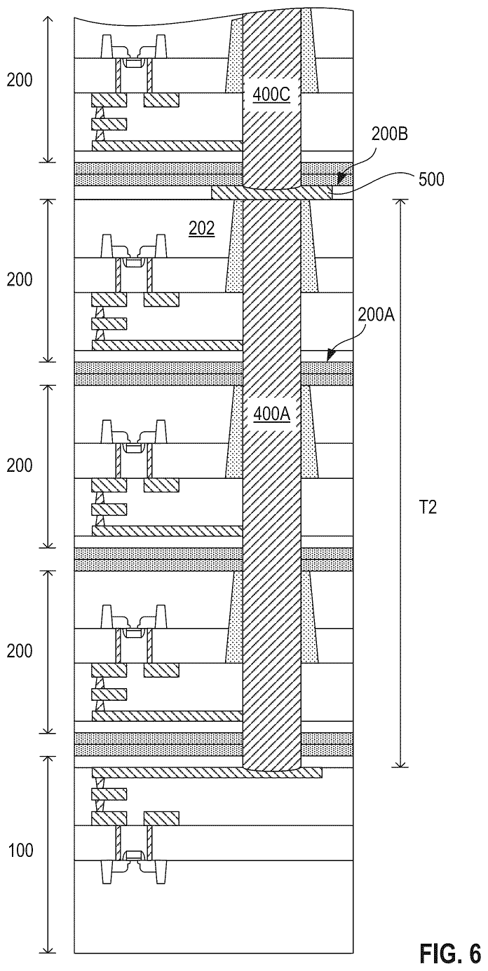

In some embodiments, each of the second semiconductor structure 200 may have a thickness in a range from about 5 μm to about 15 μm and each of the dielectric bonding layer may have a thickness in a range from about 1 μm to about 2 μm. Therefore, in the scenario where more than about three second semiconductor structures 200 are stacked over the first semiconductor structures 100, the thickness of the stack of the second semiconductor structures 200 may be greater than about 50 μm. Referring to FIG. 6, in some embodiments, the semiconductor package structure may include a feed-through connection structure 500 having a side in contact with an end of a through via structure 400A, and another through via structure 400B is landed on another side of the feed-through connection structure 500. The thickness T2 of the through via structure 400A is no greater than about 50 μm. In some embodiments, the feed-through connection structure 500 is laterally surrounded by dialectical materials. In some embodiments, the feed-through connection structure 500 is located at a surface of one of the second substrate 202 in the stack of the second semiconductor structures 200.

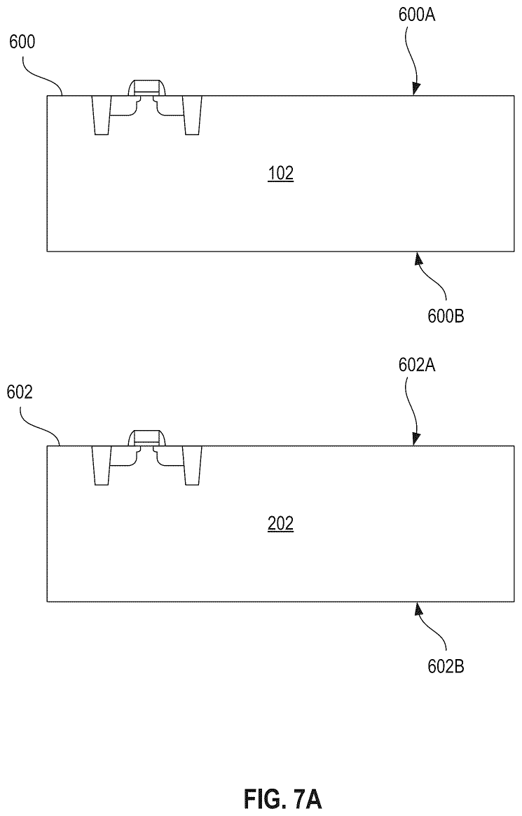

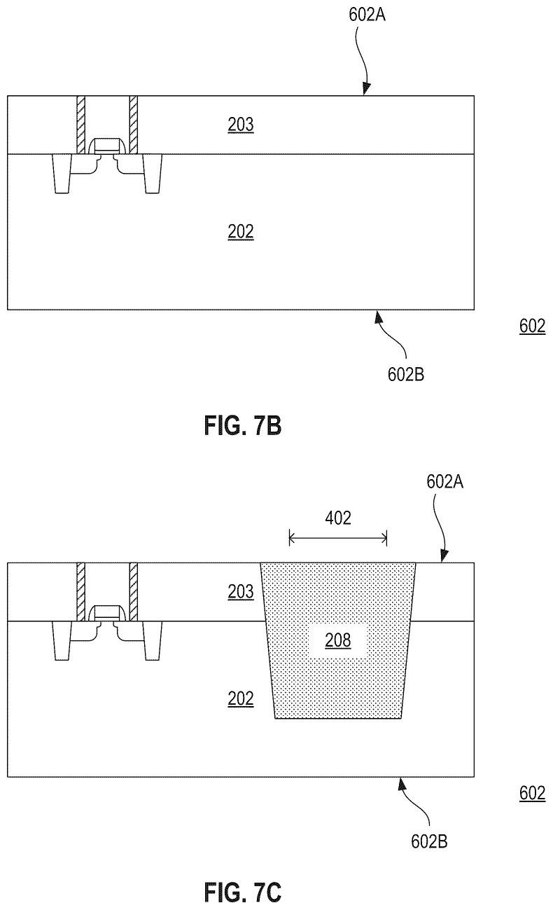

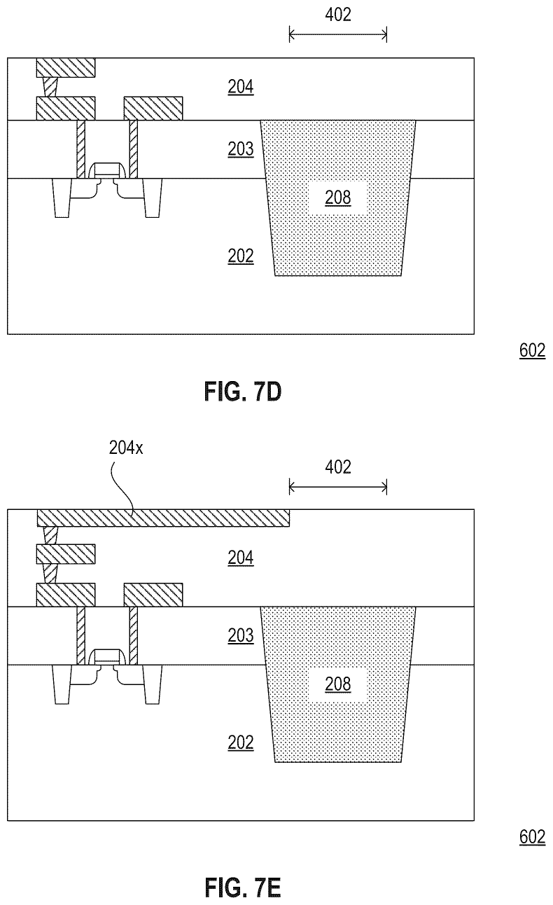

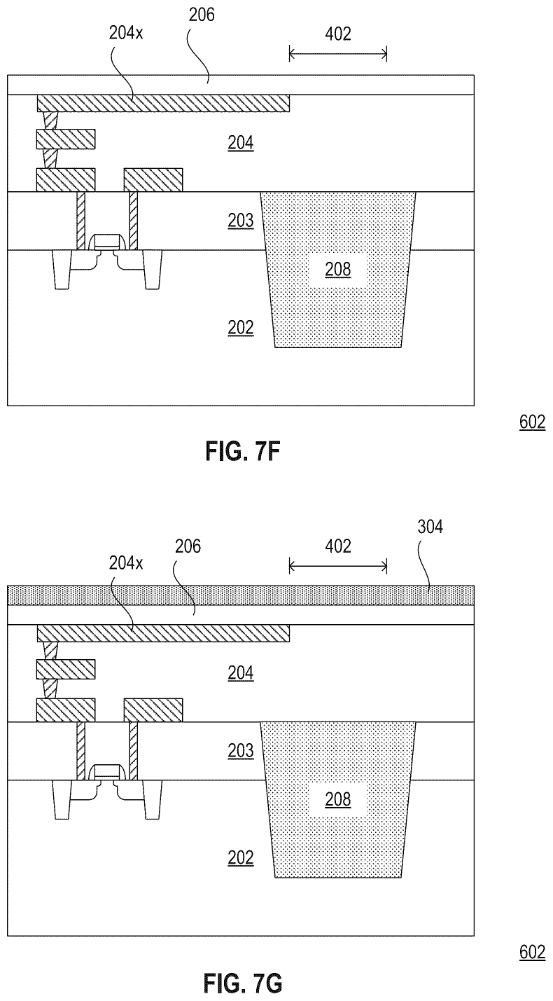

In manufacturing the semiconductor package structure as shown in FIG. 1, particularly, the operations to form the semiconductor package structure including the through via structure 400 therein, may refer to FIGS. 7A to 7G. As shown in FIG. 7A, a first device wafer 600 having a first surface 600A and a second surface 600B opposite to the first surface 600A can be received. Also, a second device wafer 602 having a third surface 602A and a fourth surface 602B opposite to the third surface 602A can be received. The first device wafer 600 and the second device wafer 602 are the wafers to be bonded. In some embodiments, the semiconductor structures (e.g., transistors, capacitors, etc.) formed on the first device wafer 600 and the second device wafer 602 may have different critical dimensions (i.e., the smallest line width implemented in the semiconductor structure on the wafers via photolithography operations). In some examples, the first device wafer 600 is a logic wafer having a plurality of logic structures. In some examples, the second device wafer 602 is a memory wafer having a plurality of memory structures. The critical dimension of the first device wafer 600 is different from that of the second device wafer 602 due to the fact that different technology nodes may be implemented to manufacture the first device wafer 600 and the second device wafer 602. In some embodiments, the critical dimension of the first device wafer 600 is smaller than that of the second device wafer 602 when a more advanced technology node is implemented in manufacturing the first device wafer 600. In other embodiments, the critical dimension of the first device wafer 600 is greater than that of the second device wafer 602 when a more advanced technology node is implemented in manufacturing the second device wafer 602. It is noted that the critical dimensions of the first device wafer 600 and the second device wafer 602 may be the same when they are manufactured by the same technology node.

In some embodiments, as shown in FIG. 7A, a transistor, such as a metal-oxide-semiconductor (MOS) structure, can be formed at a surface of the second substrate 202 in the example of the second device wafer 602. Another MOS structure can be formed at a surface of the first substrate 102 of the first device wafer 600. Next, as shown in FIG. 7B, by illustrating the operations implemented on the second device wafer 602 as an example, in the operations of forming the second MEOL structure 203 over the second substrate 202, a dielectric deposition operation, a conductive contact formation operation, and a CMP operation can be performed sequentially to form the second MEOL structure 203. Then, referring to FIG. 7C, the dielectric-filled structure 208, or called dielectric-filled trench can be formed penetrating the second MEOL structure 203 and extending into a portion of the second substrate 202. However, the vertical spanning of the dielectric-filled structure 208 is not limited thereto. For example, the dielectric-filled structure 208 can be formed in the second substrate 202, the second MEOL structure 203, or extending into the second BEOL structure 204 as shown in FIG. 7D. In some embodiments, the dielectric-filled structure 208 may penetrate the second BEOL structure 204. In some embodiments, an aspect ratio of the dielectric-filled structure 208 is smaller than about 10:1. In some embodiments, a depth of the dielectric-filled structure 208 extending into the portion of the second substrate 202 is in a range from about 1 μm to about 10 μm, depending on the semiconductor product characteristic. In some embodiments, the dielectric-filled structure 208 can be formed by forming a trench at the second MEOL structure 203 and extending into the second substrate 202, and subsequently filling the trench by dielectric materials. In some embodiments, a material of the dielectric-filled structure 208 includes silicon oxide-based material.

Referring to FIGS. 7D and 7E, in some embodiments, the second BEOL structure 204 can be formed over the second MEOL structure 203 and cover the dielectric-filled structure 208. The second BEOL structure 204 includes one or more metal lines connected by metal vias, where within a region (i.e., the TOV region 402) directly over the dielectric-filled structure 208, the second BEOL structure 204 is free from having metal lines, metal vias, or the component that has conductive materials.

In the forming of the second BEOL structure 204, the (uppermost) metal layer (Mx) 204x of the second BEOL structure 204 is formed to be in contact with the through via structure 400 formed by later mentioned operations. Therefore, a side of the metal layer (Mx) 204x should at least partially overlapped with the TOV region 402, so that the later formed through via structure 400 can be laterally in contact with the side of the metal layer (Mx) 204x.

Referring to FIGS. 7F and 7G, in some embodiments, a dielectric deposition can be performed to provide a dielectric layer 206 as a passivation over the metal layer (Mx) 204x of the second BEOL structure 204. Next, the second dielectric bonding layer 304 can be formed over the dielectric layer for the later fusion bonding operation. In some embodiments, a material of the dielectric layer over the metal layer (Mx) 204x and the second dielectric bonding layer 304 includes silicon oxide-based material.

The second device wafer 602 prepared by the operation illustrated in FIGS. 7A-7G is the wafer be packaged in the semiconductor package structure that has a dielectric-filled trench. In other words, the semiconductor package structure in the present disclosure substantially includes a wafer without the dielectric-filled trench and one or more wafers with the dielectric-filled trench stacked over the wafer without the dielectric-filled trench. The dielectric-filled trench in each of the wafers with the dielectric-filled trench are vertically aligned, and therefore the through via structure may penetrate these dielectric-filled trenches and laterally in contact with the at least one of the metal lines in the BEOL structure of these wafers with the dielectric-filled trench. The through via structure may land on the metal line in the wafers without the dielectric-filled trench, and thereby electrically connected the wafers without the dielectric-filled trench and the wafers with the dielectric-filled trench stacked thereon.

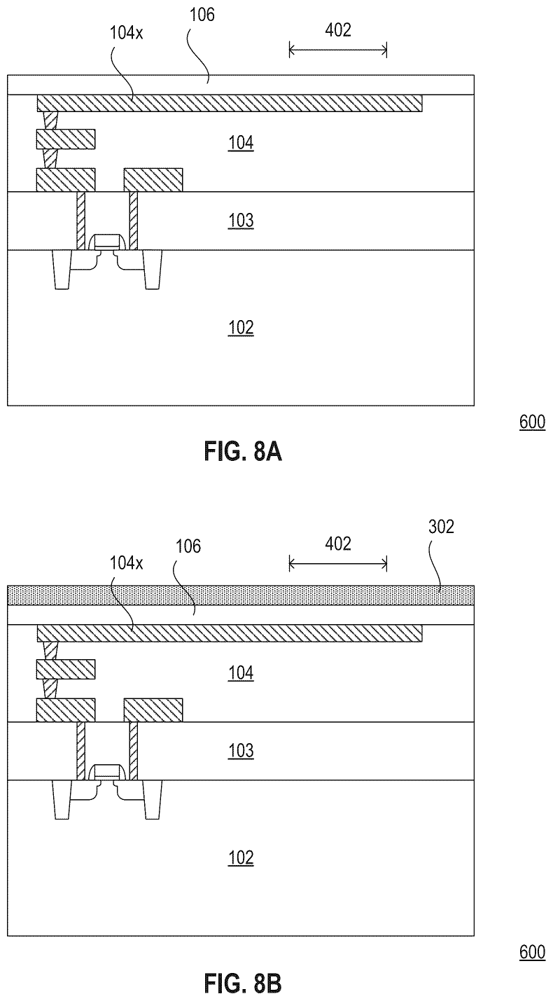

FIGS. 8A and 8B illustrate an example of preparing the wafer without the dielectric-filled trench. As shown in FIG. 8A, the first device wafer 600 can be prepared to have a MOS structure at a surface of the first substrate 102, and the first MEOL structure 103 can be formed over the first substrate 102. The first BEOL structure 104 can be formed over the first MEOL structure 103, wherein the first BEOL structure 104 includes a metal line (e.g., the metal line in the metal layer (Mx) 104x) that is at least extended to the TOV region 402 for the landing of the through via structure 400. In some embodiments, a dielectric deposition can be performed to provide a dielectric layer 106 as a passivation over the metal layer (Mx) 104x of the first BEOL structure 104. Referring to FIG. 8B, in some embodiments, the first dielectric bonding layer 302 can be formed over the first BEOL structure 104 for fusion bonding with the second dielectric bonding layer 304 of the second device wafer 602 previously shown in FIG. 7G.

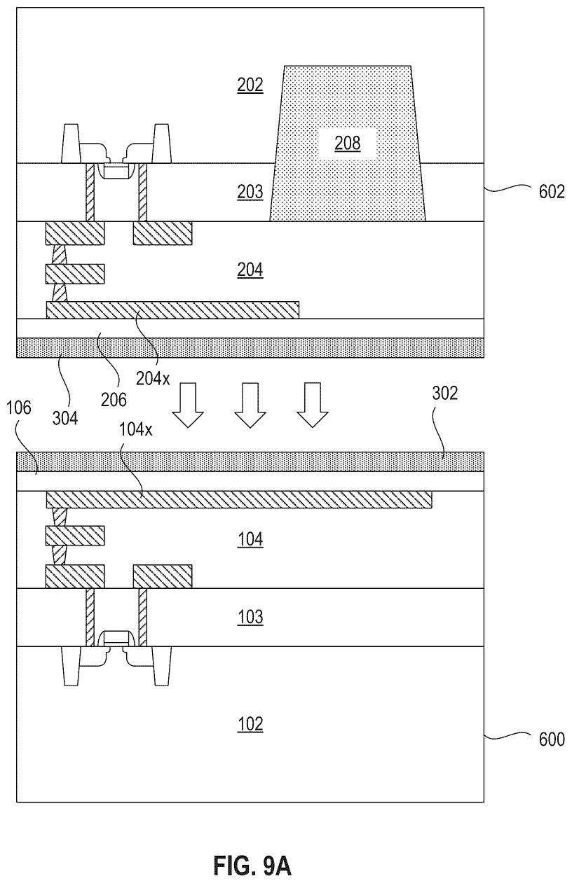

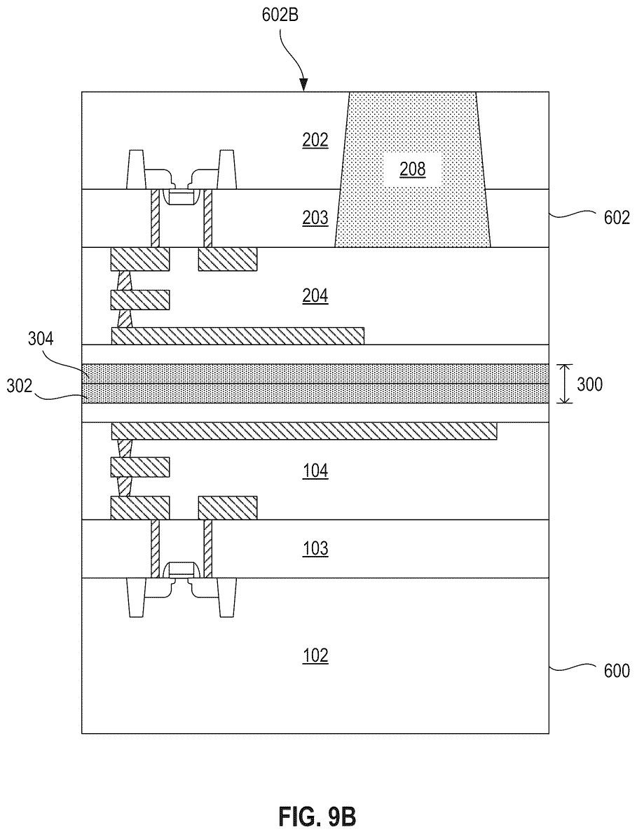

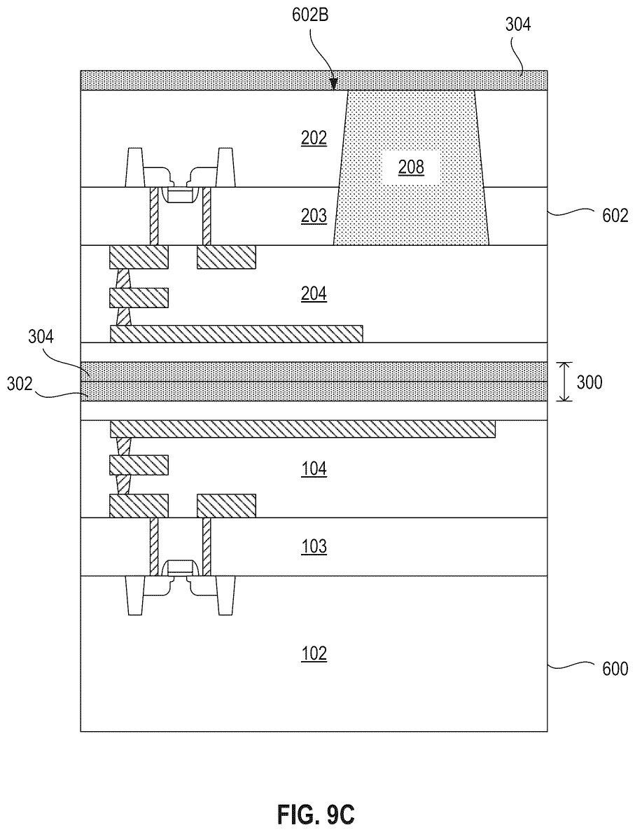

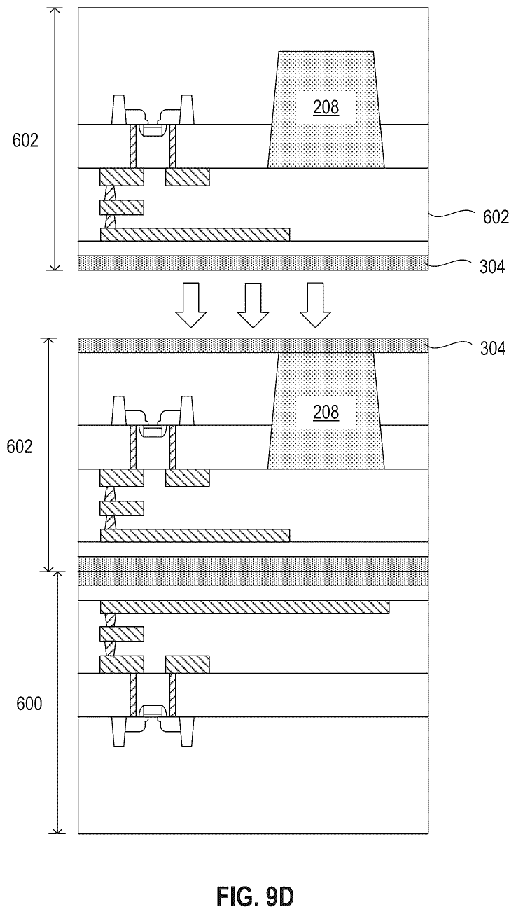

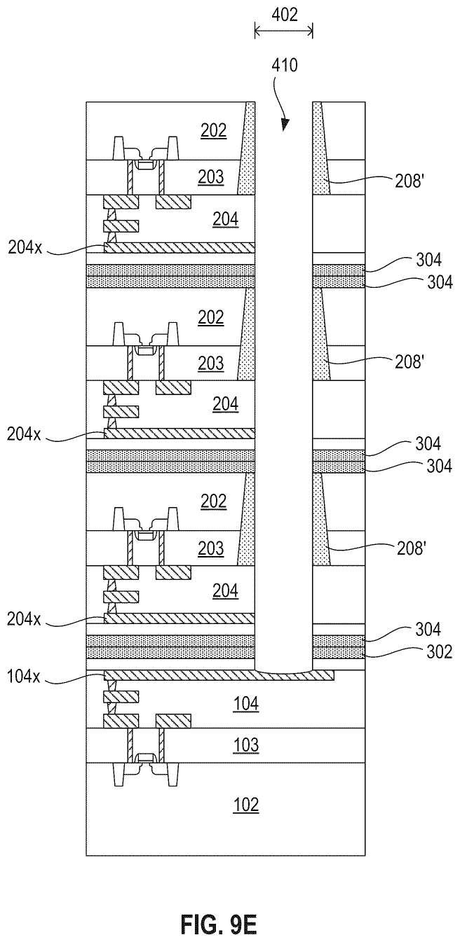

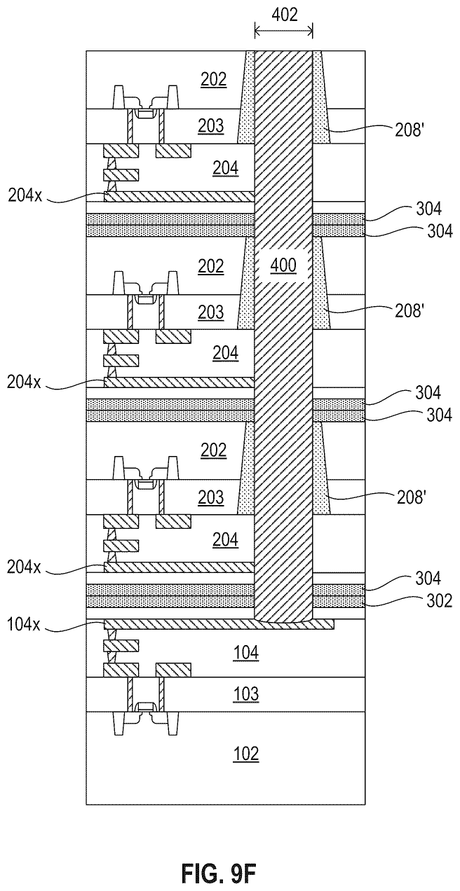

Referring to FIG. 9A, in some embodiments, the first device wafer 600 (i.e., the wafer without the dielectric-filled trench) and the second device wafer 602 (i.e., the wafer with the dielectric-filled trench) are arranged to be fusion bonded through the contact of the first dielectric bonding layer 302 and the second dielectric bonding layer 304. The first dielectric bonding layer 302 on the first device wafer 600 can thus be bonded with the second dielectric bonding layer 304 on the second device wafer 602 to form the dielectric bonding structure 300 between the first device wafer 600 and the second device wafer 602. In some embodiments, the first dielectric bonding layer 302 and the second dielectric bonding layer 304 are formed in proximity to the BEOL structure in the first device wafer 600 and the second device wafer 602, respectively. Thus, as shown in FIG. 9A, the first device wafer 600 and the second device wafer 602 are bonded in a face-to-face scheme (i.e., F2F bonding).

Referring to FIGS. 9B-9D, in some embodiments, the second device wafer 602 can be thinned in a wafer thinning operation to expose the dielectric-filled structure 208 from the second surface 602B of the second device wafer 602. In order to stack more than one second device wafer 602 over the first device wafer 600, another second dielectric bonding layer 304 can be subsequently formed on the thinned side of the second device wafer 602 in the bonded structure, as shown in FIG. 9C. This second dielectric bonding layer 304 can be used to further bond with another second dielectric bonding layer 304 of another second device wafer 602. In the example shown in FIG. 9D, each of the adjacent two second device wafers 602 stacked over the first device wafer 600 are bonded in a face-to-back scheme (i.e., F2B bonding). By repeating the operation to form the second dielectric bonding layer 304 on the second device wafers 602 for three times, for example, three second device wafers 602 can be bonded over the first device wafer 600.

To be more detailed, in the embodiments of the semiconductor package structure in the present disclosure, the memory stack may include a plurality of DRAM or HBM. Some typical memory stack may include 4, 8, 16, or 32 layers. In some embodiments, the DRAMs or HBMs are formed in the device wafers having the dielectric-filled structure (e.g., the second device wafers 602), and the stack of these DRAMs or HBMs, i.e., the memory stack, can be electrically connected by the through via structure penetrating the dielectric-filled structure, and the through via structure can land on a metal line in a logic wafer (e.g., the first device wafer 600) bonded below the memory stack.

In the embodiment that the second device wafer 602 is thinned from a surface (e.g., the surface at the second substrate of the second device wafers 602 bonded over the first device wafer 600) to expose the dielectric-filled structure and form a thinned surface, it is because the dielectric-filled structure formed in the second device wafers 602 merely extends into the second substrate instead of penetrating it.

Referring to FIG. 9E, in some embodiments, an opening 410 can be formed by etching through the second BEOL structures 204 and the dielectric-filled structure 208 in each of the second device wafers 602 within the TOV region 402, and the dielectric bonding layers along the direction of the opening 410 is also etched. The dielectric-filled structure 208′ is thus formed. Similar to the description of the through via structure 400 in FIG. 1, the opening 410 formed in FIG. 9E penetrates the stack of dielectric materials with different dielectric constants. Furthermore, the opening 410 can be substantially surrounded by a plurality of layers with different dielectric constants in the same layer. In some embodiments, the forming of the opening 410 is achieved through a single etching chemistry. The TOV region 402 is a metal-free region of the second BEOL structure 204 of the second device wafer 602 projectively under the dielectric-filled structure 208′ of the second device wafer 602. The metal line in the first BEOL structure 104 of the first device wafer 600 (e.g., the metal line in the metal layer (Mx) 104x) can be utilized as an etch stop layer in the operation of forming the opening 410 penetrating the second BEOL structures 204 and the dielectric-filled structure 208′ in each of the second device wafers 602 within the TOV region 402. In some embodiments, the metal line can thus have a dishing profile at the bottom of the opening 410. In some embodiments, a depth of the dishing profile is no less than about 120 angstroms (Å). In some embodiments, some of the metal lines in the second BEOL structures 204 (e.g., the metal lines in the metal layers (Mx) 204x) are exposed in the opening 410 and will be in contact with the later formed through via structure 400. Referring to FIG. 9F, the opening 410 can be filled by conductive material to form the through via structure 400.

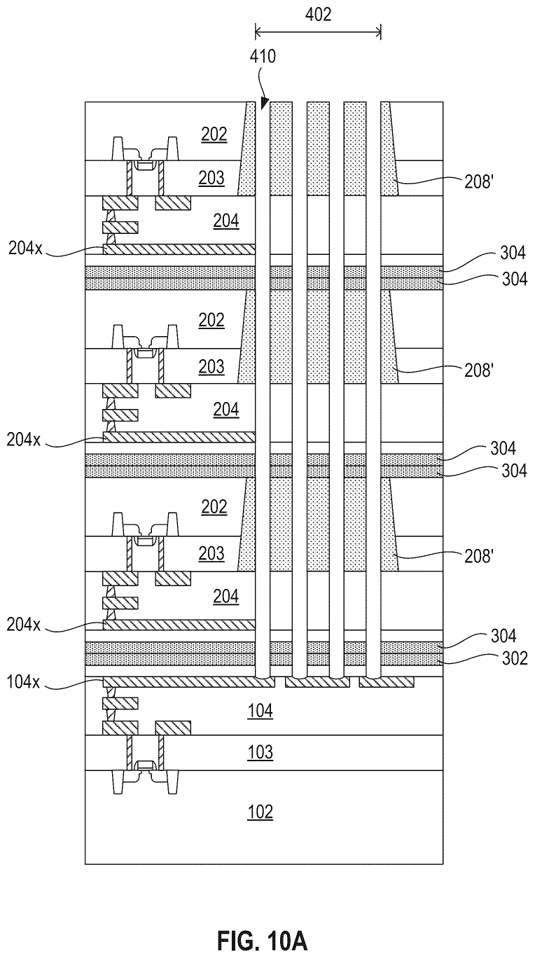

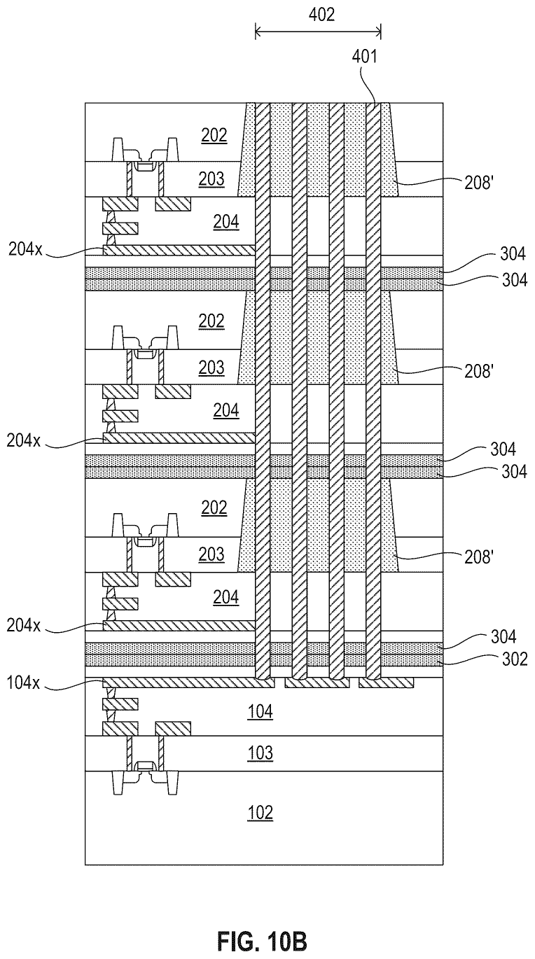

Referring to FIG. 10, in the embodiments that the through via structure 400 includes a plurality of through via units 401, a plurality of openings 410 can be formed, wherein each of the openings 410 penetrates the second BEOL structures 204 and the dielectric-filled structure 208′ in each of the second device wafers 602 within the TOV region 402, and the dielectric bonding layers along the direction of the opening 410 is also etched. The plurality of through via units 401 can be formed to land on different metal lines in the first BEOL structure 104 in the first device wafer 600 due to the package design. On the other hand, the diameter of the through via structure 400 illustrated in FIG. 9F is substantially identical to the diameter of each of the through via units 401 illustrated in FIG. 10. That is, the diameter of the through vias penetrating the stack of the second device wafers 602 does not changed in different embodiments that has different numbers of the through vias since the aspect ratio and the length of the through via are substantially the same.

In some embodiments, the thickness of the first device wafer 600 and the thickness of each of the second device wafers 602 are substantially the same.

In one exemplary aspect, a semiconductor package structure is provided. The semiconductor package structure includes a first semiconductor structure, a dielectric bonding structure, a second semiconductor structure, and a through via structure. The first semiconductor structure includes a first substrate and a first back-end-of-line (BEOL) structure over the first substrate. The dielectric bonding structure is over the first semiconductor structure. The second semiconductor structure is over the dielectric bonding structure. The second semiconductor structure includes a second BEOL structure over the dielectric bonding structure and a second substrate over the second BEOL structure. The through via structure penetrates the second semiconductor structure and the dielectric bonding structure to connect the first BEOL structure and the second BEOL structure.

In another exemplary aspect, a semiconductor package structure is provided. The semiconductor package structure includes a first wafer, a first dielectric bonding structure, a stack of a plurality of second wafers, and a through via structure. The first wafer has a first surface and a second surface opposite to the first surface, the first wafer includes a metal layer in proximity to the second surface. The first dielectric bonding structure is over the second surface of the first wafer. The stack of a plurality of second wafers is over the first dielectric bonding structure. The through via structure penetrates the stack of the plurality of second wafers and the first dielectric bonding structure, and landing on the metal layer of the first wafer.

In yet another exemplary aspect, a method for forming a semiconductor package structure is provided. The method includes the operations as follows. A first device wafer having a first surface and a second surface opposite to the first surface is received. A second device wafer having a third surface and a fourth surface opposite to the third surface is received. A dielectric-filled structure is formed from the third surface towards the fourth surface of the second device wafer. The first device wafer and the second device wafer are bonded through a dielectric bonding layer. A through via structure penetrating the dielectric-filled structure of the second device wafer and the dielectric bonding layer is formed to reach the first device wafer.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure, comprising:
a first semiconductor structure, comprising:
a first substrate; and
a first back-end-of-line (BEOL) structure over the first substrate;
a dielectric bonding structure over the first semiconductor structure;
a second semiconductor structure over the dielectric bonding structure, comprising:
a second BEOL structure over the dielectric bonding structure; and
a second substrate over the second BEOL structure; and
a through via structure penetrating the second semiconductor structure and the dielectric bonding structure to connect the first BEOL structure and the second BEOL structure.

2. The semiconductor package structure of claim 1, wherein the second substrate is a semiconductor substrate having a dielectric-filled structure formed therein, and a portion of the through via structure in the second substrate is surrounded by the dielectric-filled structure.

3. The semiconductor package structure of claim 2, wherein the second BEOL structure comprises a dielectric structure, and wherein the through via structure is arranged to penetrate the dielectric-filled structure, the dielectric structure, and the dielectric bonding structure.

4. The semiconductor package structure of claim 1, wherein a lateral surface of the through via structure is in contact with a metal layer of the second BEOL structure.

5. The semiconductor package structure of claim 1, wherein the first semiconductor structure comprises a logic processor, and the second semiconductor structure comprises a DRAM.

6. The semiconductor package structure of claim 4, wherein the through via structure is at least partially surrounded by a conductive pattern extended from the metal layer of the second BEOL structure.

7. The semiconductor package structure of claim 2, wherein the dielectric-filled structure is composed of a first dielectric material, and a dielectric constant of the first dielectric material is smaller than 2.5, from 2.5 to 3.8, or from 3.8 to 4.8.

8. The semiconductor package structure of claim 6, wherein at least ⅕ of a circumference of the through via structure is in contact with the metal layer of the second BEOL structure.

9. The semiconductor package structure of claim 1, wherein a bottom of the through via structure having a protrusion protrude towards the first BEOL structure, and a thickness of a thickest portion of the protrusion is no less than about 120 angstroms.

10. The semiconductor package structure of claim 1, wherein an aspect ratio of the through via structure is less than about 10:1.

11. A semiconductor package structure, comprising:
a first wafer having a first surface and a second surface opposite to the first surface, the first wafer comprises a metal layer in proximity to the first surface;
a first dielectric bonding structure over the first surface of the first wafer;
a stack of a plurality of second wafers over the first dielectric bonding structure; and
a through via structure penetrating the stack of the plurality of second wafers and the first dielectric bonding structure, and landing on the metal layer of the first wafer.

12. The semiconductor package structure of claim 11, wherein each of the second wafers of the stack comprises:
a third surface and a fourth surface opposite to the third surface;
a device section in proximity to the fourth surface;
an interconnect section in proximity to the third surface; and
a dielectric-filled structure penetrating the device section and in contact with the interconnect section,
wherein the through via structure is arranged to penetrate the dielectric-filled structure.

13. The semiconductor package structure of claim 12, further comprising a feed-through connection structure in contact with the fourth surface of one of the second wafers, the feed-through connection structure being further in contact with an end of the through via structure.

14. The semiconductor package structure of claim 11, wherein the through via structure continuously penetrates at least three of the second wafers in the stack.

15. The semiconductor package structure of claim 11, wherein the through via structure is surrounded by dielectric materials of at least two different dielectric constants.

16. A method for forming a semiconductor package structure, the method comprising:
receiving a first device wafer having a first surface and a second surface opposite to the first surface;
receiving a second device wafer having a third surface and a fourth surface opposite to the third surface;
forming a dielectric-filled structure from the third surface towards the fourth surface of the second device wafer;
bonding the first device wafer and the second device wafer through a dielectric bonding layer; and
forming a through via structure penetrating the dielectric-filled structure of the second device wafer and the dielectric bonding layer to reach the first device wafer.

17. The method of claim 16, further comprising:
bonding at least one another second device wafer over the bonded second device wafer prior to forming the through via structure,
wherein each of the second device wafers is penetrated by the through via structure.

18. The method of claim 16, further comprising:
forming a BEOL structure over the third surface after the forming of the dielectric-filled structure;
forming a first dielectric bonding layer and a second dielectric bonding layer over the first surface of the first device wafer and the third surface of the second device wafer, respectively;
arranging the first dielectric bonding layer of the first device wafer to bond with the second dielectric bonding layer of the second device wafer to form the dielectric bonding layer in between the first device wafer and the second device wafer;
thinning the second device wafer from the fourth surface until exposure of the dielectric-filled structure and form a thinned fourth surface; and
forming a third dielectric bonding layer over the thinned fourth surface.

19. The method of claim 16, wherein forming the through via structure comprises:
forming an opening in the dielectric-filled structure, a through oxide via region of a BEOL structure of the second device wafer projectively under the dielectric-filled structure of the second device wafer, and the dielectric bonding layer, to expose a metal layer of the first device wafer through a single etching chemistry; and
filling a conductive material in the opening.

20. The method of claim 19, wherein the opening is surrounded by dielectric materials of at least two different dielectric constants.
